(19) United States
(12) Patent Application Publication
(10) Pub. No.: US 2016/0083838 A1
(43) Pub. Date: Mar. 24, 2016

(54) Systems, Devices, and/or Methods for Managing Coatings

(71) Applicant: Directed Vapor Technologies International, Inc., Charlottesville, VA (US)

(72) Inventors: Derek Hass, Charlottesville, VA (US); Balvinder Gogia, Charlottesville, VA (US); Susie Eustis, Charlottesville, VA (US)

(73) Assignee: DIRECTED VAPOR TECHNOLOGIES INTERNATIONAL, INC., Charlottesville, VA (US)

(21) Appl. No.: 14/863,169

(22) Filed: Sep. 23, 2015

Related U.S. Application Data
(60) Provisional application No. 62/053,899, filed on Sep. 23, 2014.

(51) Int. Cl. C23C 16/448; C23C 16/455; C23C 16/30; C23C 16/503

(52) U.S. Cl. CPC C23C 16/4481; C23C 16/503; C23C 16/45557; C23C 16/308

(57) ABSTRACT

Certain exemplary embodiments can provide a method, which can comprise depositing a coating on a substrate. The coating can be deposited via a plurality of plasma source units directed toward a carrier gas. The carrier gas can comprise a coating material from a source vapor. The coating material can be directed toward the substrate via the carrier gas in a chamber under vacuum.

### CROSS-REFERENCES TO RELATED APPLICATIONS

This application claims priority to, and incorporates by reference herein in its entirety, pending U.S. Provisional Patent Application Ser. No. 62/053,899, filed Sep. 23, 2014. This application is related to issued U.S. Pat. No. 7,014,889 (having an issue date of Mar. 21, 2006), which is incorporated by reference in its entirety.

### BRIEF DESCRIPTION OF THE DRAWINGS

A wide variety of potential practical and useful embodiments will be more readily understood through the following detailed description of certain exemplary embodiments, with reference to the accompanying exemplary drawings in which:

FIG. 1 illustrates an exemplary DVD system 1100 and their implications on light elements in a vapor;

FIG. 2 illustrates a configuration of an exemplary plasma activated DVD system 2100 constructed to achieve some balancing of plasma flux with carrier gas energy;

FIG. 3A illustrates a configuration of an exemplary plasma activated DVD system 3100 comprising two plasma source units constructed to balance plasma flux and to allow substantially uniform access of the source vapor to the substrate with the angle of the plasma source units' longitudinal axis parallel to the crucible top;

FIG. 3B illustrates a configuration of an exemplary plasma activated DVD system 4200 comprising two plasma source units constructed to balance the plasma flux and to allow substantially uniform access of the source vapor to the substrate with the angle of the plasma source units' longitudinal axes forming an angle θ (which can vary from 0 to 90 degrees);

FIG. 4 is a block diagram of an exemplary system 4100;

FIG. 5 is a block diagram of an exemplary system 5100;

FIG. 6 is a block diagram of an exemplary system 6100;

FIG. 7 is a block diagram of an exemplary system 7100; and

FIG. 8 is a flowchart of an exemplary embodiment of a method 8000.

### DETAILED DESCRIPTION

Certain exemplary embodiments can provide a method, which can comprise depositing a coating on a substrate. The coating can be deposited via a plurality of plasma source units directed toward a carrier gas. The carrier gas can comprise a coating material from a source vapor. The coating material can be directed toward the substrate via the carrier gas in a chamber under vacuum.

Substrates can be coated by reactive or non-reactive evaporation via systems, devices, and/or methods known as physical vapor deposition (“PVD”). Improved systems, devices, and/or methods for plasma activated vapor depositions on a substrate in a vacuum have been developed and can be called DVD. Certain exemplary embodiments improve DVD via novel deposition devices, systems, and/or methods used to create plasma activated DVD coatings while maintaining proper composition control and allowing deposition onto a wide range of substrates such as on electrically conductive substrates, non-conductive substrates, porous substrates, large substrates, and/or substrates with non-line-of-sight (“NLOS”) regions, etc.

Certain exemplary embodiments can be particularly useful in the creation of plasma activated DVD coatings while maintaining proper composition control and allowing deposition onto a relatively wide range of substrates (such as conducting, non-conducting, large size, NLOS, and porous). Different applications of exemplary embodiments are discussed to show the ability to obtain the desired films and highlight the performance advantages of the disclosed embodiments. One example is deposition of a solid state electrolyte, lithium phosphorus oxynitride (“LiPON”) for Li-based battery applications where the ratio of the different elements in the solid state film are substantially optimized to obtain relatively high ion conducting performance and fast deposition processing, which reduces production costs relative to other approaches. Another example is deposition of an oxidation resistance bond coat onto turbine engines components to increase the adhesion of the thermal barrier coating to the underlying superalloy substrate. Accurate levels of light elements can establish good oxidation resistance and interaction with the underlying substrate. Plasma assisted deposition of coatings without significant light element leeching is desired to increase the energy of the vapor deposited atoms. In general, the density and crystallinity of vapor deposited coatings is dependent on the ability of incident adatoms to diffuse from their incidence positions to vacant, low energy sites on the growing lattice. If sufficient surface diffusion occurs, a nearly perfect crystal lattice can result.

If not, porosity in the coating can result as well as an amorphous structure. The adatom surface mobility is affected by the parameters of the vapor species energy, the vapor species translation energy, the latent heat of condensation and the vapor composition; together with the substrate temperature, deposition rate and surface topology. When the mobility is high, adatom surface diffusion occurs by atoms “jumping” to low energy sites on the crystal lattice. The jump frequency can be approximated by an equation of Arrhenius form:

υ=υₒexp(−Q/κT)

where υ is the jump frequency, υₒ is the jump attempt frequency, Q is the vapor species energy, κ is Boltzmann's constant and T is the absolute temperature of the substrate. To increase the coating density and crystallinity beyond that obtainable by substrate heating alone, the kinetic energy of depositing atoms can be increased to raise adatom surface mobility. This can be achieved using plasma activation, where a plasma is used to ionize vapor atoms and a substrate bias is used to attract the ionized atoms to the substrate (thus increasing the energy of the vapor atoms during impact). Plasma activation in DVD is performed by a hollow-cathode plasma source unit capable of producing a high-density plasma in the system's gas and vapor stream. Hollow cathode plasma technology used in DVD is able to ionize a large percentage of all gas and vapor species in the mixed stream flowing towards the coating surface. The plasma generates ions that can be accelerated towards the coating surface by either a self-bias or by an applied electrical potential. Increasing the velocity (and thus the kinetic energy) of ions by using an applied potential allows the energy of depositing atoms to be varied and controlled, affecting the atomic structure of coatings. In general, the greater the energy of the depositing atoms, the denser the microstructure of the coating.

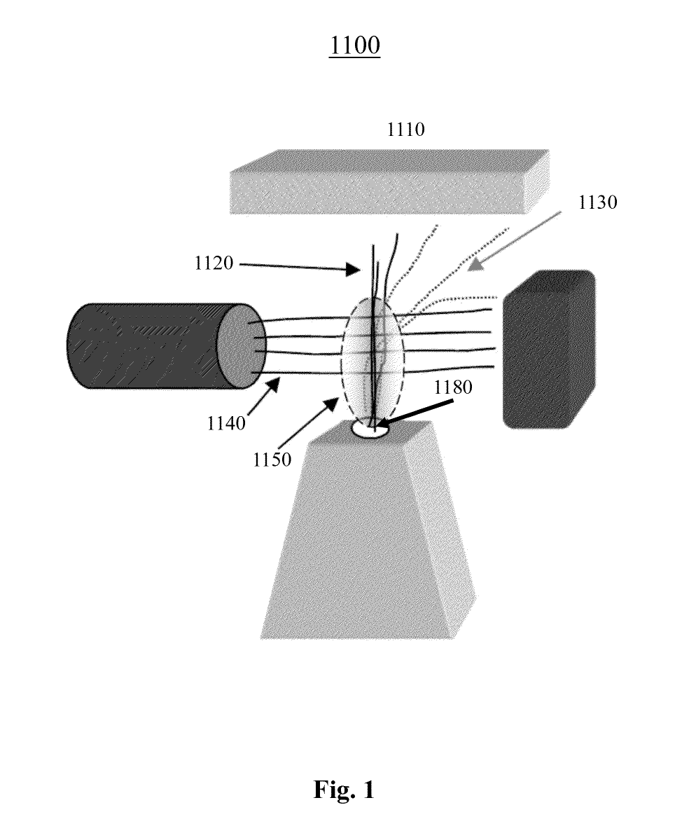

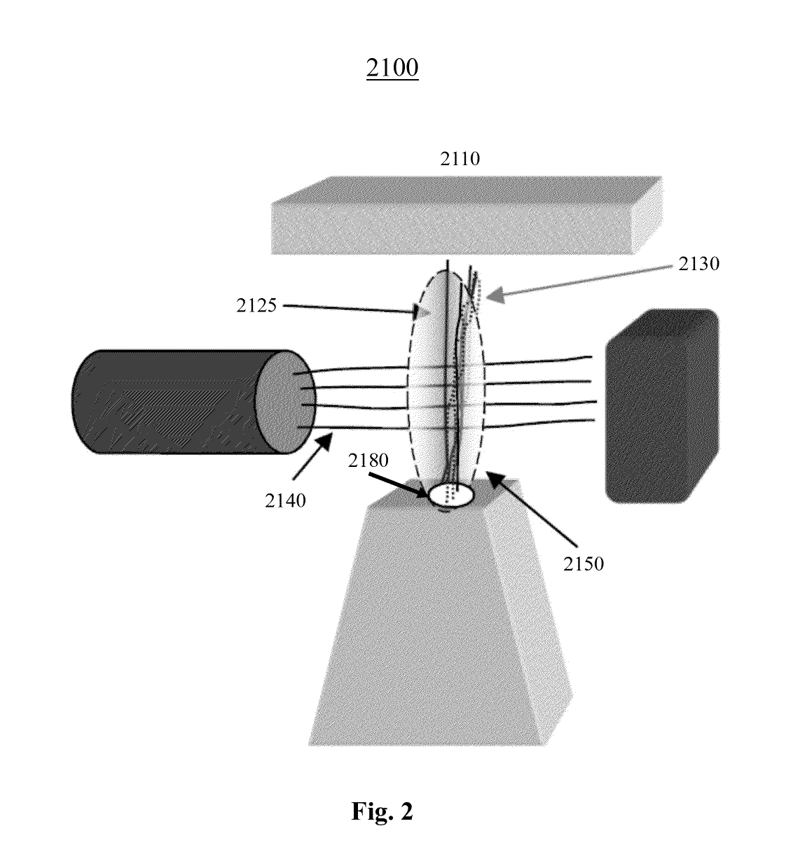

FIG. 1 illustrates an exemplary DVD system 1100 and their implications on light elements in a vapor. System 1100 comprises a substrate 1110, a plasma source unit 1120, a light element vapor path 1130, plasma flux 1140, a source vapor 1180, and a carrier gas 1150. In order to deposit layers which overcome certain limitations, one or more the following approaches can be used.
A) The energy of the carrier gas can be balanced with the energy of the plasma gas jet such that the light elements are able to traverse the plasma to reach the substrate. Conditions have been developed which allow the penetration of the light elements through the plasma stream to reach the substrate. This is accomplished through use of carrier gases with more kinetic energy, which increase the momentum to carry the light elements through the plasma stream.
B) Use a dual plasma system to balance the plasma flux from two directions at once. FIG. 2 illustrates a configuration of an exemplary plasma activated DVD system 2100 constructed to achieve some balancing of plasma flux with carrier gas energy. System 2100 comprises a substrate 2110, a heavy element path 2125, a light element vapor path 2130, plasma flux 2140, a source vapor 2180, and a carrier gas 2150. A different approach to balance the plasma flux with the need for the light elements to reach the substrate is to use multiple plasma source units, such that the plasma flux does not provide a net directionality to the source vapor as it reaches the substrate.

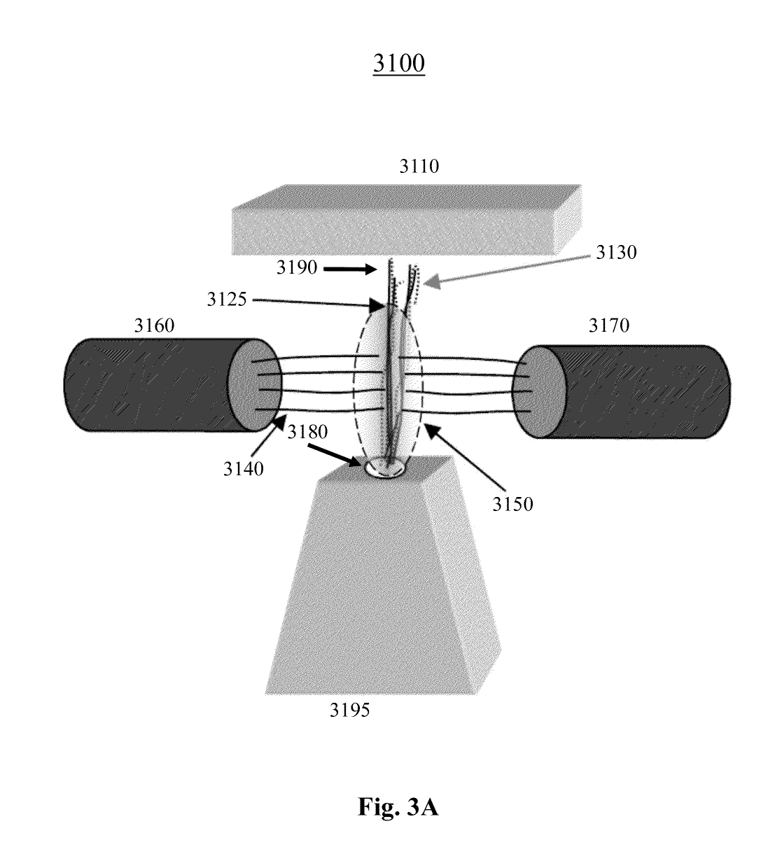

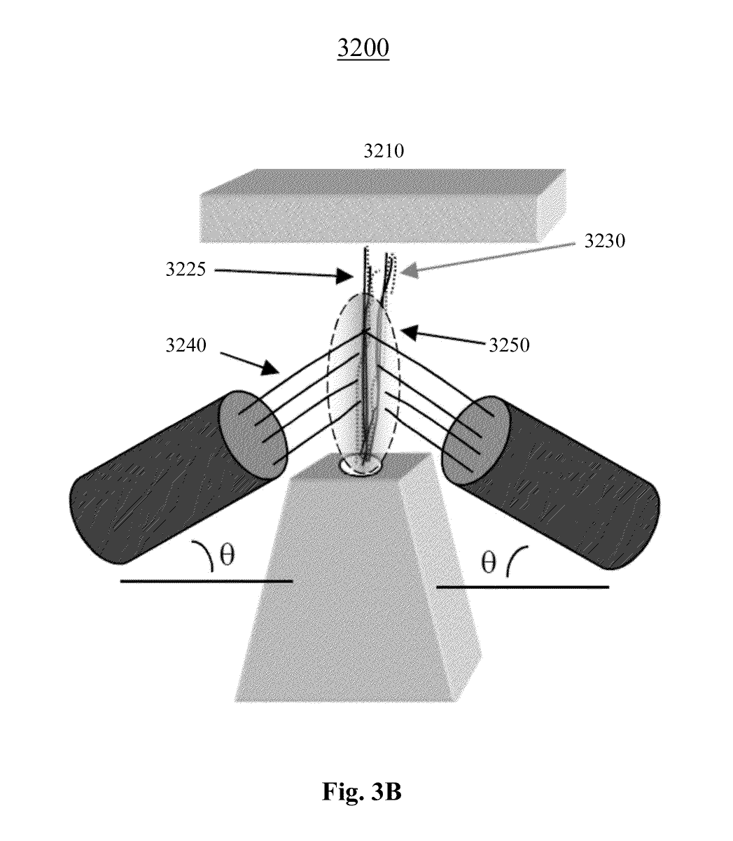

FIG. 3A illustrates a configuration of an exemplary plasma activated DVD system 3100 comprising two plasma source units constructed to balance plasma flux and to allow substantially uniform access of the source vapor to the substrate with the angle of the plasma source units' longitudinal axis parallel to a top of crucible 3195. System 3100 comprises a substrate 3110, a heavy element path 3125, a light element vapor path 3130, plasma flux 3140, a source vapor 3180, and a carrier gas 3150. Crucible 3195 is constructed to hold material used to form source vapor 3180.

Certain exemplary embodiments comprise a plurality of plasma source units, such as a first plasma source unit 3160 and a second plasma source unit 3170, each of which can be directed toward carrier gas 3150. Carrier gas 3150 can comprise a coating material 3190 from at least a first source vapor 3180. Coating material 3190 can be directed toward substrate 3110 via carrier gas 3150 in a chamber under vacuum. The plurality of plasma source units can be constructed to ionize atoms of the first source vapor and atoms of the carrier gas. Wherein substrate 3110 is coated with coating material 3190 via directed vapor deposition. The plurality of plasma source units constructed to balance plasma flux for two directions at once such that the plasma flux does not provide a net directionality to coating material 3190 as coating material 3190 reaches substrate 3110 and allows substantially uniform access of coating material 3190 to substrate 3110. In certain exemplary embodiments, the plurality of plasma source units can cause substrate 3110 to be coated with LiPON or other material.

In certain exemplary embodiments, an angle of emission direction of each the plurality of plasma units is substantially parallel to a crucible top in the chamber. A cathode of at least one of the plurality of plasma source units can be substantially coaxial with an anode of the at least one of the plurality of plasma source units. In other embodiments, an angle of emission direction of each the plurality of plasma units relative to each other is between 0 and approximately 90 degrees (see, e.g., system 3200 of FIG. 3B. In certain exemplary embodiments, a direct or alternating current bias of between approximately 0 and +/−500 volts is used to attract plasma generated ions or electrons to the substrate. A DC voltage, variable from zero to approximately 300 V, having a unipolar pulsed or bipolar pulsed DC voltage or a medium frequency AC voltage that is coupled to the substrate or the substrate holder, can be applied as a bias voltage. A power source constructed to provide energy to each of the plurality of plasma source units is utilized. In certain exemplary embodiments, the carrier gas can comprises air, helium, argon, and/or nitrogen, etc. In certain exemplary embodiments, a pressure ratio between the chamber and carrier gas 3150 is between approximately seven and approximately fifteen.

System 3100 can coat substrate 3110 with an initial conducting layer, followed by an active cathode material layer, followed by an ion conducting layer (e.g., LiPON), wherein ion conducting layer is between approximately five nanometer and approximately one micrometer in thickness. In certain exemplary embodiments, the coated substrate is constructed for use in a turbine engine component.

Certain exemplary embodiments can comprise a substrate holder for holding the substrate. In certain exemplary embodiments, a DC voltage can be applied. The DC voltage can be variable from zero to approximately 300 V, having a positive pole or a negative pole that is coupled to the substrate or the substrate holder as a bias voltage. The DC voltage can be unipolar or bipolar pulsed.

FIG. 3B illustrates a configuration of an exemplary plasma activated DVD system 3200 comprising two plasma source units constructed to balance the plasma flux and to allow substantially uniform access of the source vapor to the substrate with the angle of the plasma source units' longitudinal axes forming an angle θ (which can vary from 0 to 90 degrees). System 3200 comprises a substrate 3210, a heavy element path 3225, a light element vapor path 3230, plasma flux 3240, and a carrier gas 3250.

Via use of multiple plasma systems to balance the plasma flux to allow uniform access of the source vapor to the substrate, the angle of the plasma source units can be parallel to the crucible top or at an angle θ (which can vary from 0 to 90 degrees). Instead of using a single plasma source unit, which might have the plasma flux directed away from the substrate, a plurality of plasma source units can form a plasma flux directed at the source vapor, but can be constructed to not significantly alter the path of any source vapor on the way to the substrate. The plasma source units can be aimed directly at each other as shown in FIG. 3A or they can be angled as shown in FIG. 3B. Generated electrons from one or more of the plurality of plasma sources can be regulated for direction through variations in a quantity of the carrier gas passing through the system, wherein a flow rate of the carrier gas is between approximately 0.01 to approximately 2 standard liters per minute.

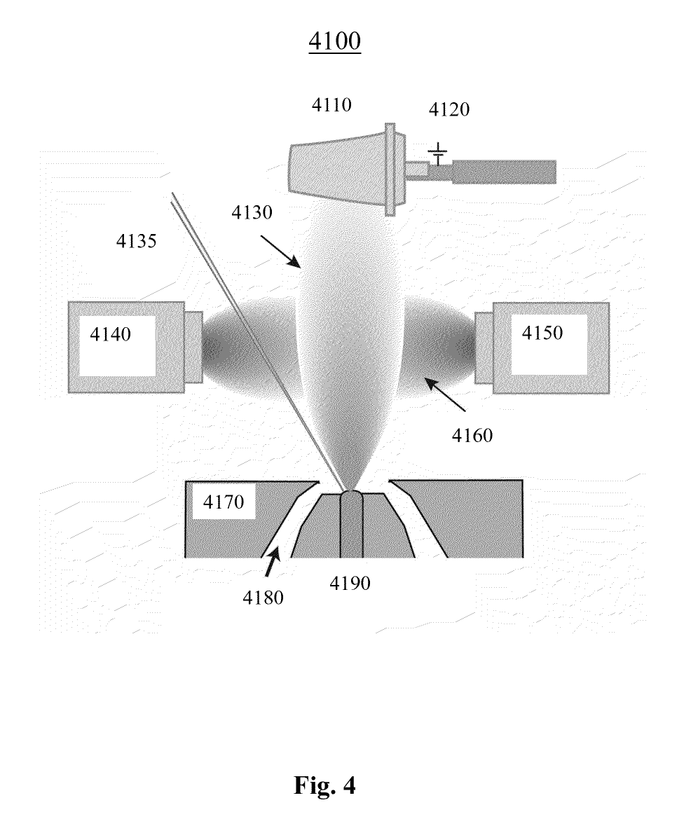

FIG. 4 is a block diagram of an exemplary system 4100, which comprises a substrate 4110, a bias 4120 (either DC or AC), a vapor flux 4130, a scanning electron beam 4135, a first plasma source 4140 (i.e., cathode/anode), a second plasma source 4150 (i.e., cathode/anode), a plasma flux 4160, a nozzle 4170, a carrier gas 4180, and a source vapor 4190.

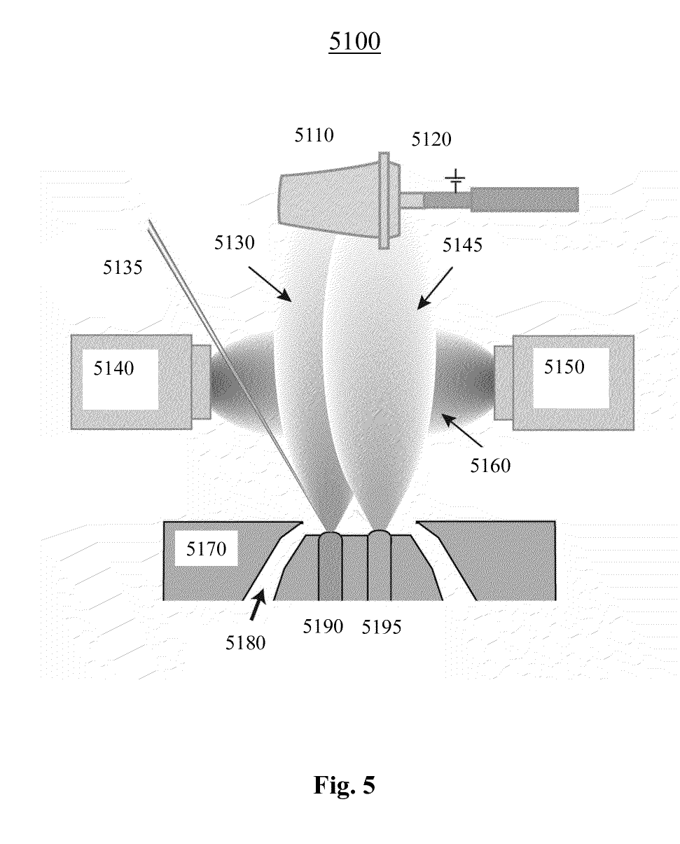

FIG. 5 is a block diagram of an exemplary system 5100, which comprises a substrate 5110, a bias 5120 (either DC or AC), a first vapor flux 5130, a second vapor flux 5145, a scanning electron beam 5135, a first plasma source 5140 (i.e., cathode/anode), a second plasma source 5150 (i.e., cathode/anode), a plasma flux 5160, a nozzle 5170, a carrier gas 5180, and a first source vapor 5190, and a second source vapor 5195.

In certain exemplary embodiments, a first source vapor can be generated from a plurality of adjacent sources scanned and heated by a single electron beam source. In other embodiments, the first source vapor can be one of a plurality of source vapors. The carrier gas can be a single gas stream. The plurality of source vapors can be substantially surrounded by the single gas stream. In other embodiments, the first source vapor can be one of multiple source vapors. The carrier gas can be a plurality of gas streams. The multiple source vapors can be substantially surrounded by the plurality of gas streams. The first source vapor can be generated from multiple, adjacent sources scanned and heated by a single electron beam source. A distance between a part of the plasma source and the source vapor can be adjustable.

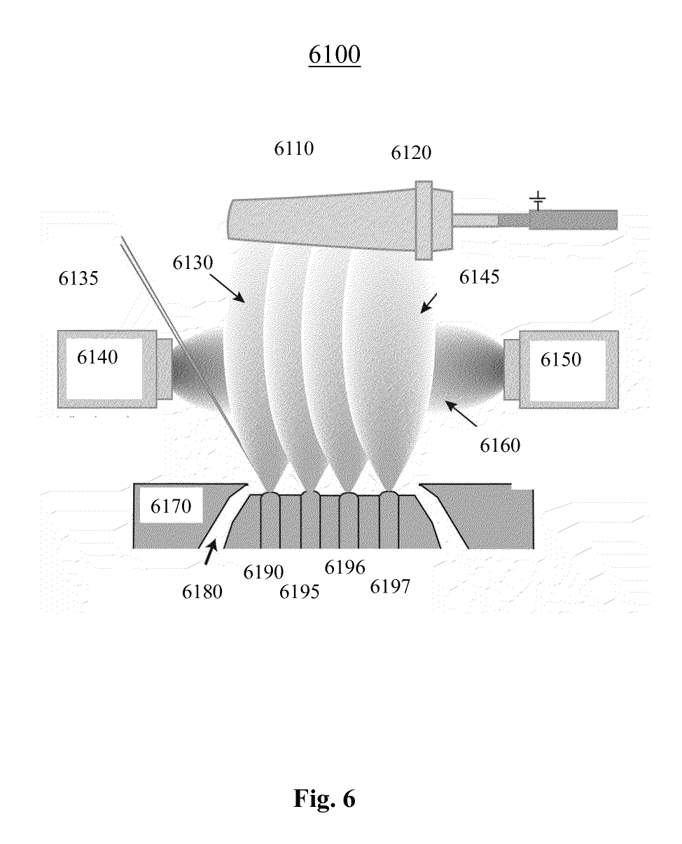

FIG. 6 is a block diagram of an exemplary system 6100, which comprises a substrate 6110, a bias 6120 (either DC or AC), a first vapor flux 6130, a second vapor flux 6145, a scanning electron beam 6135, a first plasma source 6140 (i.e., cathode/anode), a second plasma source 6150 (i.e., cathode/anode), a plasma flux 6160, a nozzle 6170, a carrier gas 6180, and a first source vapor 6190, a second source vapor 6195, a third source vapor 6196, and a fourth source vapor 6197.

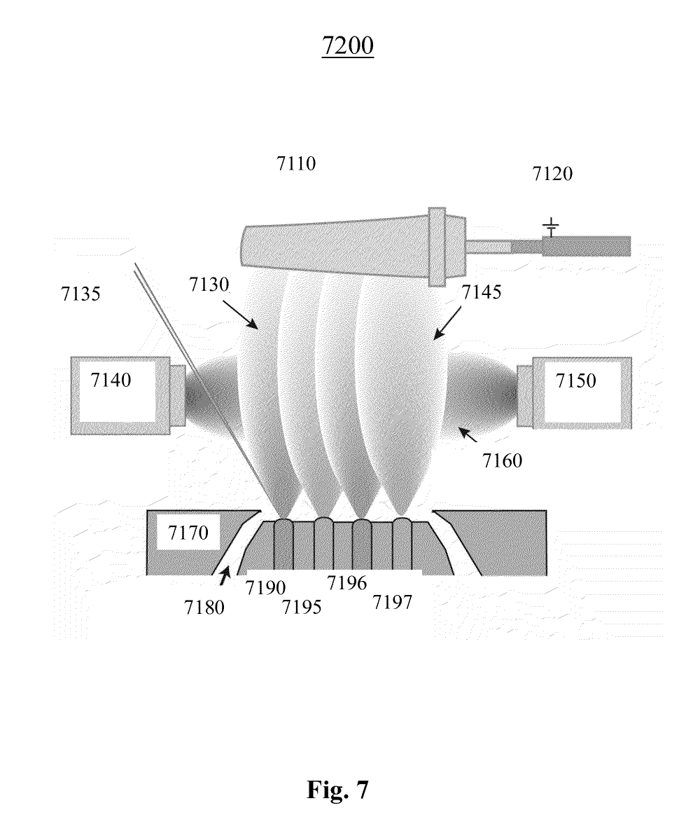

FIG. 7 is a block diagram of an exemplary system 7100, which comprises a substrate 7110, a bias 7120 (either DC or AC), a first vapor flux 7130, a second vapor flux 7145, a scanning electron beam 7135, a first plasma source 7140 (i.e., cathode/anode), a second plasma source 7150 (i.e., cathode/anode), a plasma flux 7160, a nozzle 7170, a carrier gas 7180, and a first source vapor 7190, a second source vapor 7195, a third source vapor 7196, and a fourth source vapor 7197.

The design of systems utilizing a plurality of plasma source units can have the following advantages:
plasma deposition of relatively dense coatings at lower substrate temperatures than alternate approaches;
a substantially co-axial cathode and anode configuration with magnetic enhancement plasma design creates relatively large plasma fields outside the cathode;
creates a long distance plasma field via the geometry of two hollow cathodes and relatively rapid switching of cathode polarity;
creates a substantially uniform plasma field via arranging cathodes (i.e., plasma source units) on each side of a substrate;
not geometrically constrained by anode configuration;
enables coating of larger components (such as a turbine disk);
higher pressure operation enabled through use of paired hollow cathodes to boost field strength;
carrier gas flow can be decreased (as compared to exemplary alternative systems) to increase the uniformity of source vapor reaching substrate;
higher operating voltage allows higher energy input to the vapor deposition atoms for ionization and increasing kinetic energy; and/or
improved reliability via use of magnetic activation rather than using a heating block, etc.

A pair of hollow cathodes was selected due to the high pressure regime of the DVD process, and a distance between the cathodes of approximately one (1) meter was utilized to allow large plasma field for production scale coating of components. Several design considerations were evaluated prior to installation of the plasma source unit including the size of the assembly, desired installation angle, cooling requirements, and distance to substrates. Redesign of some internal components an exemplary production scale coater was performed in order to allow implementation of the plasma activation system into a current chamber.

In certain exemplary embodiments, the plasma source unit can be coupled to a flange with integral electrical, gas, and chilled water feed-throughs so that the plasma source unit can be easily installed and removed. There are three orientation approaches that are suitable for installation of the plasma in certain production scale DVD chambers.

Housings for the plasma system can be used in certain exemplary embodiments to allow for relatively safe operation of the plasma equipment. In such embodiments, a housing can be utilized to substantially enclose the power, water, gas, and provides physical and x-ray shielding of the entire assembly. To finalize the utilized designs a manufacturer of the equipment was provided with design parameters and measurements. The installation locations of the plasma and the locations of existing chamber structure and attached equipment were considered while creating these designs.

To aid the specification of the plasma housings, measurements from both sides of the DVD chamber were taken and the basic envelope of the design for the enclosures was sent to the equipment manufacturer. The enclosures for the plasma system can provide electromagnetic and X-ray shielding, as well as protect operators from contact with high tension/high current electrical connections during operation. The enclosures can also be designed to be large enough to contain substantially all of the equipment related to the plasma, as well as the substrate drive system used for exemplary DVD systems. Equipment for exemplary systems can comprise:
plasma source units;
power input;
back current conductor;
multiple cables with digital input/output;
a plurality (e.g., eight) water cooling watchdogs; and/or
a plurality of mass flow controllers (e.g., two).

Each enclosure can compromise an access door which can be hinged at the bottom to allow maximum access to the interior. Mounting of the enclosures can use the bolt circle of a blank (e.g., a 500 millimeter blank) on each side of the chamber and can be designed so that removal can be accomplished quickly. Internal and external gas lines and water lines for an exemplary production system were coupled to the enclosures and equipment with easily removed quick disconnects. Electrical connections to the plasma enclosures were designed for easy removal (e.g., no permanently soldered connections). A main triaxial cable to power the plasma source units was attached to a conduit at a right rear area of the chamber. A feedthrough location for connection to plasma triaxial main power cable was selected as the area where the main plasma power cable is fed into the enclosure in an exemplary embodiment. This area was chosen because of ample internal clearance for the cable connections and because there was already an external support structure nearby to which the power cable could be attached. Locations for water, gas, and electronic connections were used to connect water lines to the enclosures. These locations were chosen because they allowed connection to existing water and gas lines with minimal changes to the existing lines in the exemplary system. In addition, these locations allowed connections to be kept organized and compact.

In the pump side enclosure, the location of the plasma source units was dictated by the geometry of the chamber and the installed crucible and nozzle parts. The conductor was installed to be close to the plasma field for magnetic coupling, but as a result passed through the coating area of the chamber. To allow close magnetic coupling, the flange for the conductor was placed on the same 500 mm flange as the hollow cathode plasma, but to allow maximum clearance for substrate motion it was placed on the flange as far towards the back of the chamber as was possible. This allowed enough room to rotate large substrates and did not block the flow of the vapor or plasma plumes.

The plasma systems can be powered and controlled by equipment located in two cabinets. One cabinet comprises a transformer and the power supplies for the plasma and the other cabinet comprises control equipment for the system. The user interface can be via a laptop computer.

The ion current density profile was desired to be measured once the plasma was installed into the production scale coater. This test was used to verify that the plasma installation and operating parameters were near optimal for the conditions inside of the production scale coater. The data gathered also allows mapping of the plasma current distribution inside the chamber. To measure the current, a 6″×6″ array of small collectors was fabricated. The system was run first in the high vacuum environment, without any carrier gas flow or evaporation to insure no problems are encountered. Follow this test, the plate array was used with carrier gas.

An ion current density array was utilized to detect the ion current density at different locations during plasma operation was fabricated. Metal disks were placed on a backing plate, with a ceramic standoff to isolate each disk from each other and the chamber. This set-up enabled measuring of the ion current density at different locations with the desired plasma conditions.

The plasma activation units are installed onto an exemplary chamber at opposite sides with a distance of approximately 860 mm between them. The middle of the chamber was used as the reference position or zero, as this location was approximately equally distant between the two hollow cathode plasma source units. A plasma field, with a meaningful ion current density, can be created in the region where substrates are coated with installation of the tandem hollow cathode plasma source system. All samples tested showed the same general trend for the current density, where increasing the plasma current (and resulting plasma power) increases the ion current density, and a minimum in the current density was observed near the midpoint. The addition of carrier gas further pronounces the decreased plasma field as the carrier gas was predicted to reduce the distance that the plasma field can reach.

An exemplary in-line plasma system using the plasma to direct the source vapor to the substrate can result in substantially all of the species reaching the substrate to have interacted with the plasma stream for maximum activation of the source vapor.

By using the plasma flux to turn the source vapor, a high percentage of the evaporated source material can be directed and deposited onto relatively small areas, particularly when relatively large bias voltages are applied to the substrate. This results in a concentration of the source vapor onto relatively small substrate regions. In such a configuration only small pressures were used for the carrier gas, as it was desired that the plasma flux overwhelm the carrier gas to determine the flow of the source vapor. Relatively small substrates were coated with this method, which can be useful for certain applications to enhance the source vapor and plasma interaction in a relatively small volume.

In certain exemplary embodiments, plasma can be de-coupled from general source vapor. Such embodiments utilize plasma to ionize gas flux but without significant interaction with carrier gas and source vapor.

The location of the plasma source units well outside of the region where the carrier gas and source vapor are located allows the substantially uninterrupted flow of source vapor to the substrate. Thus, the light elements are not significantly leached. The plasma does not significantly alter the path of the source vapor. The species that is desired to be ionized, such as nitrogen for coating applications such as layers in thin film batteries, wear coatings, and ceramic nitrides can interact with a plasma source unit which is located at relatively high angle. Ranges of angles are important, and can be determined by the geometry of a given system to the crucible. The range of angles desired is determined by the physical dimensions of the given parts, but typically between varies between approximately forty five (45) and approximately ninety (90) degrees. This allows the ionization of one component (such as a nitrogen gas stream which can be part of many gases such as argon, helium, neon, krypton, air or a mixture of these gases directed towards the substrate) to be separated from the unintended leaching of the light elements from the source vapor. The ionization of components is useful in applications where breaking of chemical bonds prior to incorporation into the deposited film is desired. One example is where it is desired to incorporate nitrogen into a coating through breaking the chemical bond of the source gas such as N₂, N₂ from unfiltered air, or ammonia prior to reaching the substrate surface.

As an exemplary application, for deposition of alloy bond coats onto components of turbine engine components, the momentum of the carrier gas can be increased to improve the amount of light elements that reach the substrate. In a test, coatings were deposited and the composition was determined using EDS to compare the coatings major component composition to the desired composition. Coating compositions measured using EDS analysis with different processing conditions In one run, where plasma activation was employed, a larger than desired drop in the Aluminum (“Al”) content was observed (likely due to the difficulty in Al adatoms passing through the plasma at certain plasma conditions). By implementing the plasma, the microstructure of the coatings could be made relatively dense.

Significantly, the use of an Ar carrier gas led to greatly improved compositions (similar to those of the source rod) while still resulting in good coating density and deposition rate. The improved composition obtained when using Ar as the carrier gas is related to the ability of the heavier Ar atoms (relative to He) to alter the direction of the plasma in the DVD chamber towards the substrate, thus limiting the loss of Al vapor from the vapor flux.

When no plasma was used, the aluminum atoms are able to effectively reach the substrate. However, when the plasma is turned on, the amount of aluminum reaching the substrate decreases significantly when He is used as the carrier gas. Shifting to use of Ar as the carrier gas allows substantially all of the aluminum to reach the substrate by balancing the kinetic energy of the source vapor with that of the plasma clearing gas which move perpendicular to the substrate to direct light elements, such as aluminum preferentially away from the substrate.

In addition to changing the gas to heavier carrier gases, increased pressure ratios (ratio of the carrier gas to the chamber pressure) can also be used to alter the kinetic energy of the source material as it travels towards the substrate. Previous experience has shown that a pressure ratio around three (3) is too low for the light elements to reach the substrate. The carrier gas has a pressure ratio between the pressure upstream of a choked nozzle and the chamber pressure can be between approximately one and approximately one thousand. Good performance has been demonstrated with pressure ratios around the range of approximately seven (7) to approximately fifteen (15). Higher pressure ratios could also provide desirable results. By increasing the pressure ratio through changing the shape of the nozzle or increasing the pressure of the carrier gas prior to entering the vacuum chamber, the amount of light elements deflected from the substrate will decrease. Thus, the increased pressure ratio will help the lighter elements to reach the substrate. Coatings have been deposited with dual-plasma activation, and the compositions of the coatings were measured at different locations with either EDS or wavelength-dispersive X-ray spectroscopy (“WDS”) (microprobe), where two different source rod compositions have been investigated, OHC-A, Ni-35Cr-12Al-0.1Y at %, and LCF-A, Ni-13Al-7.5Cr-1Si-0.05Y at %. The composition of test samples was determined with EDS at three locations in either point or area mode through the thickness of the coating (at %). The Al concentration increased through the coating deposition to approach that of the source rod, while the chromium (“Cr”) concentration decreased through the coating deposition to approach that of the source rod. At the beginning of the coating deposition (after approximately fourteen (14) minutes of equilibration of a new LCF-A source rod), near the coating-substrate interface the Al concentration is below that of the source rod, while the Cr concentration is above that of the source rod. Near the end of the coating process (approximately 83 minutes of total coating time), near the surface of the coating the concentration of the Al and Cr is closer to that of the source rod. Thus, this coating is initially Cr enriched and Al deficient, but these values approach that of the source rod after evaporation. The compositions of multiple coatings from LCF-A source rods were determined. The Al content of the samples was found to be similar to that of the source rod in samples deposited with previously used source rods. The Cr content of the samples was found to be less than that of the source rod in samples deposited with previously used source rods. This suggests that Al concentrations can be achieved that are very similar to source rod through variation of the plasma geometry.

Another exemplary test was run for the deposition of solid state electrolyte LiPON for battery applications. Due to both the desire to increase the use of renewable energy and the ever expanding electronic device capability, the push to develop improved batteries is a large area of current research. Li-based batteries have been identified as able to increase energy density over traditional batteries. However, many challenges remain to develop Li-based batteries that are affordable to manufacture, safe, meet lifetime cycling requirements and deliver high energy density as predicted theoretically. One issue of particular importance is the very low deposition rates achievable using a baseline radio frequency (“RF”) sputtering approach for LiPON electrolyte deposition which significantly affects the affordability of depositing solid state electrolyte layers.

A battery is an electrochemical cell, or combination of multiple cells that produces an electrical current. Secondary batteries, often referred to as rechargeable batteries can be run in both the forward and reverse directions, allowing many cycles to be completed over the lifetime of the battery. Batteries function during discharge through the flow of electrons from the anode to the cathode though an electrical circuit. In order to complete the circuit an electrolyte is placed between the anode and the cathode which allows the transport of ions to balance the net charge transfer of the electrons in the circuit. If electrons flow quickly through the electrolyte, the battery will not produce a useful current. The electrolyte can be chosen to inhibit electron flow and to be stable in the electrochemical window between the two electrodes. Li-based batteries are widely believed to represent the future of battery technology due to lithium's high reduction potential, and low density. The function of the electrolyte in a secondary Li-based battery is to provide nearly perfect transport of the Li ions (i.e., the transport number of Li ions is one), while providing a high resistance to electrons enabling the selective and reversible transport of species. The ionic conductivity is a measure of the ability of the material to transport ions through a given distance. Higher ionic conductivities are desired to allow increase in the charging and discharging speed. The thickness of the films will also have an effect on the performance of the battery. Layers that are thinner will require less time for the ions to move through the film, thus electrolytes with lower ionic conductivities can be tolerated if they can prevent battery shorting even when the layers are thin (e.g., <˜2 μm).

Perhaps the most important solid state electrolyte material is LiPON glass. LiPON has two advantages that have made it the solid electrolyte of choice: i) it has high Li ion conductivity and ii) it is stable in the presence of Li electrodes. The LiPON chemistry is based on a lithium phosphorus oxide glass to which the addition of nitrogen leads to the substitution of nitrogen atoms for oxygen to effectively expand the average Li—O bond length through either a linkage or structural distortion with the N and Li. This nitridation of the lithium phosphorus oxide glass lowers the activation energy of the Li ion transport from approximately 0.74 electron volts (“eV”) to approximately 0.57 eV, and therefore increases the mobility of the Li ions in a glassy film. The nitrogen incorporation into the lithium phosphorus oxide glass structures also enhances the chemical and thermal stability of the glass, thereby increasing the stability of the structure to the presence of Li metal.

The LiPON electrolyte layer is desired to be relatively thin and substantially pin-hole free for optimum performance. RF sputtering has been used to deposit LiPON with ionic conductivity as high as 2 (±1) siemens per centimeter (“S/cm”). However, the deposition rate of LiPON layers is very slow with RF sputtering, typically just 1-2 nm/min. Other technologies such as pulsed laser deposition (PLD), ion-beam assisted deposition (IBAD), plasma enhanced chemical vapor deposition (PECVD), and electron-beam physical vapor deposition (EB-PVD) can be utilized to deposit LiPON films. However, none of these techniques has found commercial success or has the high throughput potential of DVD. Such techniques have led to relatively high costs of manufacture for these layers, a high per part manufacturing cost, and/or have significantly increased the cost of bringing these products to the market. This high processing cost has also limited the use of LiPON in other types of Li based batteries (such as Li-air batteries). Thus new processing approaches which enable the rapid, cost effective deposition of LiPON into solid state battery cells are highly desired. Such approaches also allow for the deposition of other battery layers (i.e. cathode, anode, and current collectors) so that the entire system can be assembled with a single high throughput system. Li-air batteries are of particular interest due to their ultra-low density resulting from the use of oxygen from ambient atmospheres as the cathode, thereby reducing the amount of material that must be maintained within the battery structure in order to function. However, in Li-air batteries a barrier between the air source and the anode is particularly important as oxygen is deliberately being introduced to the battery cell, which is often sealed to reduce the interaction of an anode such as lithium (“Li”) with ambient oxygen. Ambient air typically also contains water vapor, where a barrier layer is also desired between the air inlet and the anode. LiPON is a good candidate to form this barrier layer as it is stable in contact with lithium anodes, in oxygen environments, and reacts relatively slowly with water vapor.

A number of different electrolytes can be utilized to enable rechargeable Li based batteries, but only a few are stable with a Li electrode. Such compatibility is important as Li is a highly desirable electrode in rechargeable battery applications due to the low mass and high energy density of the metal, leading to the ability to store a large amount of energy in a light weight electrode. The low stability of Li in ambient conditions as well as in contact with aqueous solutions also limits the choice of electrolytes that can be used with Li electrodes. In addition to the initial instability of lithium films in contact with oxygen, dendrites are also observed to grow on Li electrodes in contact with organic solutions and polymer film electrolytes. The dendrites can short out the batteries after significant growth, and can cause thermal run-away leading to the possibility of explosion. As a result, the use of solid state electrolyte layers that are stable in contact with Li, are also of interest for lithium-air and larger lithium based batteries to form stable battery structures with the use of Li anodes. LiPON is an important electrolyte for Li-based batteries where the performance depends on the compositions of the layer, where a small amount of nitrogen doping is utilized for increased ionic conductivity and increased film stability. The amount of lithium present is also important to insure the high mobility of Li, which leads to high ionic conductivity. Thus, preferable deposition conditions allow for the incorporation of nitrogen into the film, primarily from gas based nitrogen sources such as N₂, air, and ammonia. Therefore, the nitrogen can be passed though the plasma to break the bonds of the sources of nitrogen to form an ionic atom which can be incorporated into the growing film. While this is performed, the lithium can reach the substrate so that it may also be incorporated into the film. The plasma activation techniques described herein are all methods by which a LiPON layer can be deposited with optimal composition for battery applications.

LiPON can be utilized for dual purposes, as an electrolyte and as a protective layer over Li metal in an air or liquid battery to ameliorate hazardous conditions. To enable the use of LiPON as a protective layer in a battery with a second liquid electrolyte, LiPON can be deposited onto conducting or non-conducting substrates. The LiPON can be deposited as a thin layer to improve the ionic conductivity of the structure. LiPON cannot be deposited directly onto Li metal, as the interface will grow a nitride or oxide film before the LiPON glass layer is able to develop a stable composition. The LiPON can be deposited onto structures that are stable in contact with the other electrolytes or components of the battery. One such structure is a separator film, which are currently used in Li-ion batteries. Separator films provide transport for the liquid electrolyte to the anode, while containing the liquid. However, separator films have lower ionic conductivities than. LiPON film, and do not provide the same level of safety as LiPON in contact with a Li anode. Therefore a layer of LiPON could be deposited onto the surface of the separator film as a protective layer for the lithium anode, which could then be used. A separator film in Li based batteries can be utilized when liquid electrolytes are used. Primarily this is found in Li-ion based batteries, where the anode is lithium ion based. However, in order to increase the energy density of the battery it would desirable to use lithium metal as the anode. However, when lithium metal contacts liquid and polymer electrolytes, dendrites form on the surface of the anode. As the dendrites grow, they have been shown to breach the gap between the anode and the cathode, which leads to shorting out of the circuit, failure of the battery, and even more concerning, can lead to an explosion.

LiPON can be deposited onto non-conducting layers. In a battery there are components which conduct electricity and components which prevent electrical conduction. As the role of the LiPON film is to substantially prevent electrical conductivity, it can be deposited onto nonconductive substrates, such as separator films or polymer electrolyte layers. Since the plasma is used to enhance the deposition of the desired layer through the creation of ions, a bias can be applied to the substrate to attract the ions created in the plasma to the substrate. Metallic substrates use a direct current (“DC”) bias as any residual charge is transferred to the substrate. However, with non-conducting substrates it is still desirable to use a bias to attract the ions to the substrate. Thus an alternating current (“AC”) bias can be used to diffuse the build-up of charge on the substrate surface by periodically reversing the polarity of the surface charge, neutralizing the surface.

An AC bias can be used to attract plasma generated ions to the substrate. Many other substrates on which plasma activated DVD could effectively act can be envisioned (such as, without limitation, flexible polymer support structures, rigid polymer films, silica substrates, and/or silicon wafers, possibly with a silicon oxide layer on top, glass supports, particularly thin glass roll films, etc.).

Initial conducting layers such as gold or copper could be deposited onto the substrates, followed by an active cathode material such as carbon, lithium manganese oxide, lithium cobalt oxide, vanadium oxide, or titanium dioxide, any or a combination of which could optionally be deposited onto the substrate prior to deposition of LiPON. Then an additional optional layer of a polymer electrolyte or solid separator/liquid electrolyte layer can be deposited prior to the deposition of the LiPON.

In order to be effective, the LiPON layer substantially blocks the access of air, oxygen, and/or any solution to the Li anode. Therefore the layer can be relatively dense and have virtually no through pores. The fewer number of pores, the thinner the LiPON layer can be. The LiPON layer can be between approximately 5 nm and approximately 1 μm thick, preferably between approximately 1.00 nm and approximately 1 μm thick.

The development of more complex solid state battery architectures is also of high interest to enable even greater energy densities per unit area. Fabrication of solid state batteries can incorporate a substrate to provide the support structure which the thin battery layers can be deposited onto. The mass of the substrate can have a significant impact on the energy density of the final battery, as the battery layers themselves have very little mass and provide high energy density per mass. The substrate does not contribute significantly to the energy content of the battery, and therefore can significantly decrease the practical energy density of solid state batteries from the theoretical predictions. Thus, fabricating solid state batteries for higher power applications can utilize relatively large areas for battery deposition. One approach to reduce the area and increase battery power per unit area is to use a three dimensional (“3-D”) battery structure.

In a 3-D structure the cathode, anode and electrolyte can be assembled into 3-D arrangements where the electrodes are separated by the electrolyte and not shorted out through direct contact. This represents a processing challenge to fabricate the desired structures and infiltrate the electrolyte and second electrode into the 3-D structures. Many different approaches can be used to generate these structures, such as interdigitated electrodes though 3-D mold formation, use of anodic alumina membranes, network foams, or template opal and inverse opal structures. In such cases, an electrolyte layer can be applied onto and/or into non-line-of-sight regions of the substrate. To enhance non line-of-sight deposition, a bias is applied onto the substrate (DC for conducting and AC for non-conducting substrate) to induce the source vapor to travel inside the structure. In addition, carrier gas conditions which promote source vapor penetration through the porous substrate may be used to get the source vapor to the desired location. These preferable carrier gas conditions include, without limitation: using increased gas pressure ratios ideally in the range of approximately 10-30, carrier gas flow rates such as approximately 10-30 standard liters per minute that result in chamber pressures in the approximately five (5) to approximately one hundred (100) Pa range, and using heavier carrier gases such as Ne, Ar or Kr. Additionally, changing the gas condition during coating deposition can increase the uniformity of coating into NLOS regions.

A diffuse electron beam can be used to vaporize source material. In order to vaporize the source material an energy source is used. One such source is an electron beam or an electron beam gun. To facilitate evaporation of large sources, and multiple sources the electron beam can optionally be scanned, so that one electron beam can be used to evaporate multiple sources.

Relatively rapid scanning of the electron beam can be used to expose multiple targets substantially simultaneously via (a) splitting an electron beam into multiple beams. To aid in manufacturing on the production scale, larger evaporation zones can be created through the use of multiple source rods, placed accordingly in the deposition chamber, where rapid scanning of a single electron beam can be used to evaporate multiple sources.

In the preparation of a lithium based battery, a single processing sequence is desired to facilitate manufacturing. During this process initial oxide layers would first be deposited in a closed chamber, where reactive oxygen, nitrogen or other species could be flowed, creating the desired layers, such as a cathode of lithium cobalt oxide or lithium manganese oxide and an electrolyte such as LiPON. Then the sample would be relocated to a separated chamber, through vacuum interlocks, where the lithium metal anode could be deposited. The second chamber might not have any oxide coatings deposited in it to maintain an appropriate environment for lithium metal. After the lithium metal anode is deposited, the substrate can be maintained in an inert environment until protective environmental seal has been applied over the structure.

Prior to depositing coatings or layers for batteries, substrates may be pre-heated or pre-cooled prior to and during coating. Pre-heating the substrate can alter the microstructure of the coating by altering the energy of the vapor molecules as they approach the substrate. Densification of layers can be achieved through increasing the energy of vapor atoms, giving them sufficient energy to move to different lattice sites on the substrate before losing all energy. Also due to differential thermal expansion of different materials, various levels of stress can be achieved by coating at elevated temperatures. Heating methods can comprise resistive heaters, conduction heaters, induction heaters, electron beam scanning to heat, plasma activation heating and radiant heat. Additionally porous structures can be formed at elevated temperature due to cluster formation in the vapor flux.

Substrates can also be pre-cooled prior to and during deposition. By cooling the substrates, the temperatures can be kept low to accomplish deposition of films onto substrate with low thermal stability such as polymer films. The lowered temperature can also be used to control the stress of films for differential thermal expansion if devices are to be used at lower temperatures. Cooling can be performed through flowed fluid cooling (such as water or antifreeze), conventional heat sinks, or thermoelectric devices (solid state heat pumps), such as Peltier devices.

The nitrogen doped coatings described herein can be fabricated by using air as the reactive source of nitrogen in combination with plasma activation to break the nitrogen bond to form the desired LiPON coatings.

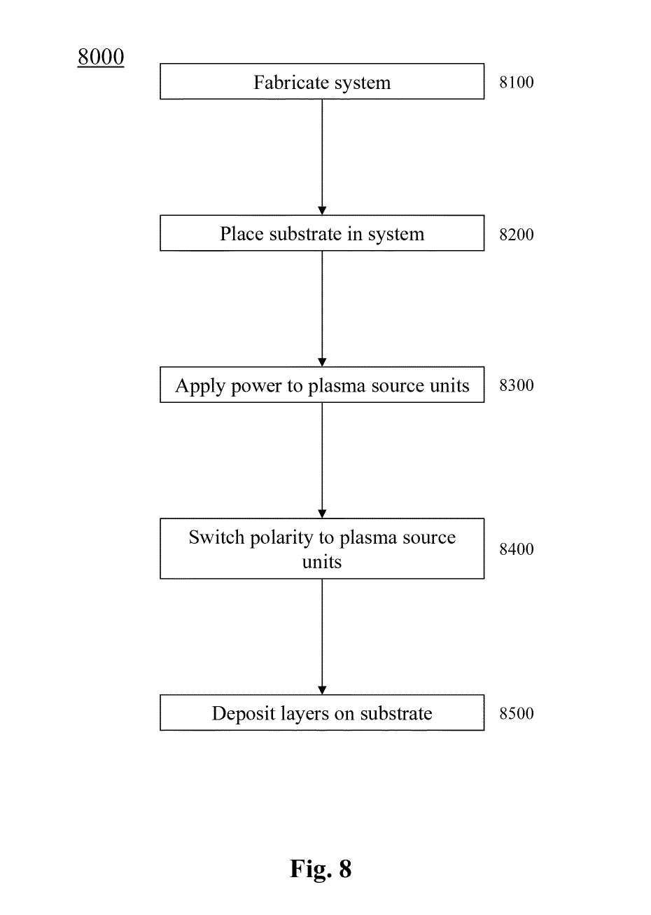

FIG. 8 is a flowchart of an exemplary embodiment of a method 8000. At activity 8100, a system comprising a plurality of plasma source units can be fabricated. At activity 8200, a substrate can be placed in the system. At activity 8300, power can be applied to the system such that the plurality of plasma source units is energized. A plasma current of at least one of the plurality of plasma source units can be applied between approximately one amp and approximately one thousand amps.

At activity 8400, a polarity of each of the plurality of plasma source units can be rapidly switched.

At activity 8500, layers can be deposited on the substrate as described herein. In certain exemplary embodiments, a coating can be deposited on a substrate. The coating can be deposited via a plurality of plasma source units directed toward a carrier gas. The carrier gas can comprise a coating material from at least a first source vapor. The coating material can be directed toward the substrate via the carrier gas in a chamber under vacuum. The plurality of plasma source units can be constructed to ionize atoms of at least the first source vapor and atoms of the carrier gas. The substrate can be coated with the coating material via directed vapor deposition. The plurality of plasma source units can be constructed to balance plasma flux for two directions at once such that the plasma flux does not provide a net directionality to the coating material as the coating material reaches the substrate and allows substantially uniform access of the coating material to the substrate. In certain exemplary embodiments, the carrier gas can comprise air, helium, argon, carbon, and/or nitrogen, etc. In certain exemplary embodiments, the carrier gas can be substantially pure nitrogen. In certain exemplary embodiments, the coating can be an ion conducting layer which can comprise LiPON. In certain exemplary embodiments, a pressure of the chamber can be between approximately two Pascals and approximately fifty Pascals.

### Definitions

When the following terms are used substantively herein, the accompanying definitions apply. These terms and definitions are presented without prejudice, and, consistent with the application, the right to redefine these terms during the prosecution of this application or any application claiming priority hereto is reserved. For the purpose of interpreting a claim of any patent that claims priority hereto, each definition (or redefined term if an original definition was amended during the prosecution of that patent), functions as a clear and unambiguous disavowal of the subject matter outside of that definition.
a—at least one.
active cathode material layer—a quantity of material deposited on a surface that is constructed to act as a negatively charged electrode via which electrons enter an electrical device.
activity—an action, act, step, and/or process or portion thereof.
adapter—a device used to effect operative compatibility between different parts of one or more pieces of an apparatus or system.
adjust—to change in a controlled manner to achieve a desired fit or result.
air—a mixture of nitrogen, oxygen, and other gases that surround the earth and form its atmosphere.
alternating current—an electric current that reverses direction at regular intervals, having a magnitude that varies in a sinusoidal manner.
and/or—either in conjunction with or in alternative to.
angle—a geometric figure formed by two lines that begin at a common point or by two planes that begin at a common line. The space between such lines or planes, measured in degrees.
anode—a positively charged electrode via which the electrons leave a device.
apparatus—an appliance or device for a particular purpose
associate—to join, connect together, and/or relate.
automatically—acting or operating in a manner essentially independent of external influence or control. For example, an automatic light switch can turn on upon “seeing” a person in its view, without the person manually operating the light switch.
bias—a voltage or current applied to an electrical device and/or system.
bipolar—an electrical current that may assume either of two polarities, neither of which is zero.
can—is capable of, in at least some embodiments.
carrier gas—a substance that acts to convey a coating material in a chamber, which substance is in a state such that the substance expands freely to fill any space available, irrespective of a quantity of the substance.
cathode—a negatively charged electrode by which electrons enter an electrical device.
cause—to produce an effect.
chamber—a substantially enclosed space or cavity.
choked nozzle—a spout at a terminus of a pipe, hose, or tube constructed to control a jet of a gas or liquid and severely restricts flow of the gas or liquid.
coat—to provide an object with a layer over a surface of the object.
coating material—a substance to be applied as a layer to a substrate.
coaxial—having a common axis.
component—a part of a larger whole.
comprising—including but not limited to.
configure—to make suitable or fit for a specific use or situation.
connect—to join or fasten together.
constructed to—made suitable or fit for a specific use or situation.
convert—to transform, adapt, and/or change.
coupleable—capable of being joined, connected, and/or linked together.
coupling—linking in some fashion.
create—to bring into being.
crucible—a container constructed to hold a substance, which container is constructed to allow the substance to be subjected to a gasifying temperature.
define—to establish the outline, form, or structure of.
device—a machine, manufacture, and/or collection thereof.
deposit—to put a layer on a surface of an object.
directed vapor deposition—a method via which a layer of a coating material is put on a surface of a substrate, wherein the layer is formed via condensation of an evaporated substance on the surface of the substrate, which evaporated substance is conveyed to the surface of the substrate via a carrier gas stream.
directionality—indicating a direction in space.
electrically conductive—constructed to convey electricity over a distance and having a resistivity of less than approximately 1 mΩ cm.
electrically non-conductive—constructed to substantially not conduct electricity and having a resistivity of greater than approximately 1 mΩ cm.
electrolyte—a liquid or gel that contains ions and can be decomposed by electrolysis.
electron beam source—a system constructed to emit a stream of electrons in a gas or vacuum.
emission direction—a primary course along which a plasma source conveys a plasma flux.
generate—to produce something.
holder—a device constructed to restrain an object from motion.
initial conducting layer—a quantity of material placed substantially as a first material on a substrate, the material being an electrically conductive material.
install—to connect or set in position and prepare for use.
ion conducting—a material via which charged atoms or molecules can permeate.
layer—a quantity of material placed on the surface of something.
LiPON—lithium phosphorus oxynitride.
may—is allowed and/or permitted to, in at least some embodiments.
method—a process, procedure, and/or collection of related activities for accomplishing something.
net—remaining after an interaction.
non-line-of-site regions—portions of something that are not visible to a human via observation from a fixed point in space.
parallel—extending substantially in a same direction, approximately equidistant at all points, and substantially not converging or diverging.
plasma—One of four main states of matter, similar to a gas, but consisting of positively charged ions with most or all of their detached electrons moving freely about.
plasma current—an electron flow applied to a plasma source
plasma flux—a flow of plasma from a plasma source.
plasma generated ions—positively charged atoms or molecules created and conveyed by a plasma source.
plasma source unit—a system constructed to impart energy to a coating material and thereby generate a plasma.
plurality—the state of being plural and/or more than one.
polarity—a relative direction of an electrical or magnetic field.
pole—a terminal of an electrical circuit.
predetermined—established in advance.
pressure—a substantially continuous physical force exerted on or against an object by something in contact with the object.
pressure ratio—a quantitative relation between two pressures showing the number of times one pressure is when mathematically divided by the other.
probability—a quantitative representation of a likelihood of an occurrence.
provide—to furnish, supply, give, and/or make available.
pulse—to modulate.
pure—substantially of a single substance.
receive—to get as a signal, take, acquire, and/or obtain.
repeatedly—again and again; repetitively.
scan—to cause an object to be traversed by an electromagnetic beam.
set—a related plurality.
source—a fount from which something is emitted.
stream—a flow of something.
substantially—to a great extent or degree.
substrate—a substance or layer upon which one or more predetermined layers are deposited.
support—to bear the weight of, especially from below.
switch—to change.
system—a collection of mechanisms, devices, machines, articles of manufacture, processes, data, and/or instructions, the collection designed to perform one or more specific functions.
thickness—a distance between opposite sides of an object.
turbine engine—a type of internal combustion engine, which has an upstream rotating compressor coupled to a downstream turbine, and a combustion chamber in between.
uniform access—having a substantially equal probability of being deposited in a given location as compared to any other location on a surface.
unipolar—an electrical current in which the peak amplitude has a single polarity and is substantially constant.
vacuum—a space in which the pressure is lower than atmospheric pressure.
source vapor—a gaseous stream that comprises a coating material to be applied as a layer to a substrate.
variation—change.
via—by way of and/or utilizing.
voltage—an electrical potential expressed in volt units.
weight—a value indicative of importance.

### Note

Still other substantially and specifically practical and useful embodiments will become readily apparent to those skilled in this art from reading the above-recited and/or herein-included detailed description and/or drawings of certain exemplary embodiments. It should be understood that numerous variations, modifications, and additional embodiments are possible, and accordingly, all such variations, modifications, and embodiments are to be regarded as being within the scope of this application.

Thus, regardless of the content of any portion (e.g., title, field, background, summary, description, abstract, drawing FIG., etc.) of this application, unless clearly specified to the contrary, such as via explicit definition, assertion, or argument, with respect to any claim, whether of this application and/or any claim of any application claiming priority hereto, and whether originally presented or otherwise:
there is no requirement for the inclusion of any particular described or illustrated characteristic, function, activity, or element, any particular sequence of activities, or any particular interrelationship of elements;
no characteristic, function, activity, or element is “essential”;
any elements can be integrated, segregated, and/or duplicated;
any activity can be repeated, any activity can be performed by multiple entities, and/or any activity can be performed in multiple jurisdictions; and
any activity or element can be specifically excluded, the sequence of activities can vary, and/or the interrelationship of elements can vary.

Moreover, when any number or range is described herein, unless clearly stated otherwise, that number or range is approximate. When any range is described herein, unless clearly stated otherwise, that range includes all values therein and all subranges therein. For example, if a range of 1 to 10 is described, that range includes all values therebetween, such as for example, 1.1, 2.5, 3.335, 5, 6.179, 8.9999, etc., and includes all subranges therebetween, such as for example, 1 to 3.65, 2.8 to 8.14, 1.93 to 9, etc.

When any claim element is followed by a drawing element number, that drawing element number is exemplary and non-limiting on claim scope. No claim of this application is intended to invoke paragraph six of 35 USC 112 unless the precise phrase “means for” is followed by a gerund.

Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such material is specifically not incorporated by reference herein.

Accordingly, every portion (e.g., title, field, background, summary, description, abstract, drawing FIG., etc.) of this application, other than the claims themselves, is to be regarded as illustrative in nature, and not as restrictive, and the scope of subject matter protected by any patent that issues based on this application is defined only by the claims of that patent.

What is claimed is:

1. A system comprising:
a plurality of plasma source units directed toward a carrier gas, said carrier gas comprising a coating material from at least a first source vapor, said coating material directed toward a substrate via said carrier gas in a chamber under vacuum, said plurality of plasma source units constructed to ionize atoms of said first source vapor and atoms of said carrier gas, wherein said substrate is coated with said coating material via directed vapor deposition, said plurality of plasma source units constructed to balance plasma flux for two directions at once such that said plasma flux does not provide a net directionality to said coating material as said coating material reaches said substrate and allows substantially uniform access of said coating material to said substrate.

2. The system of claim 1, wherein:
said plurality of plasma source units cause said substrate to be coated with LiPON or other ion conducting layers.

3. The system of claim 1, wherein:
said coated substrate is constructed for use in a turbine engine component.

4. The system of claim 1, wherein:
an angle of emission direction of each said plurality of plasma units is substantially parallel to a crucible top in said chamber.

5. The system of claim 1, wherein:
an angle of emission direction of each said plurality of plasma units relative to each other is between 0 and approximately 90 degrees.

6. The system of claim 1, wherein:
a direct or alternating current bias of between approximately 0 and 500 volts is used to attract plasma generated ions to said substrate.

7. The system of claim 1, wherein:
a direct or alternating current bias is used to attract plasma generated ions to said substrate.

8. The system of claim 1, further comprising:
a substrate holder for holding said substrate; and
a DC voltage, variable from zero to approximately 500 V, having a positive pole that is coupled to said substrate or said substrate holder as bias voltage.

9. The system of claim 1, further comprising:
a substrate holder for holding said substrate; and
a DC voltage, variable from zero to approximately 500 V, having a negative pole that is coupled to said substrate or said substrate holder as bias voltage.

10. The system of claim 1, further comprising:
a substrate holder for holding said substrate; and
a unipolar pulsed or bipolar pulsed DC voltage, or a medium frequency AC voltage, that is coupled to said substrate or said substrate holder as bias voltage.

11. The system of claim 1, wherein:
said carrier gas comprises one or more of argon, helium, neon, or krypton.

12. The system of claim 1, wherein:
a cathode of at least one of said plurality of plasma source units is substantially coaxial with an anode of said at least one of said plurality of plasma source units.

13. The system of claim 1, wherein:
said carrier gas has a pressure ratio between a pressure upstream of a choked nozzle and a chamber pressure is between approximately one and approximately one thousand.

14. The system of claim 1, wherein:
said system coats said substrate with an initial conducting layer, followed by an active cathode material layer, followed by a layer of an ion conducting electrolyte.

15. The system of claim 1, further comprising:
a crucible constructed to enable said first source vapor and at least a second source vapor.

16. The system of claim 1, wherein:
said first source vapor is generated from a plurality of adjacent sources scanned and heated by a single electron beam source.

17. The system of claim 1, wherein:
said first source vapor is one of a plurality of source vapors;
said carrier gas is a single gas stream; and
said plurality of source vapors is substantially surrounded by said single gas stream.

18. The system of claim 1, wherein:
said first source vapor is one of multiple source vapors;
said carrier gas is a plurality of gas streams; and
said multiple source vapors is substantially surrounded by said plurality of gas streams.

19. The system of claim 1, wherein:
said first source vapor is generated from multiple, adjacent sources scanned and heated by a single electron beam source.

20. The system of claim 1, wherein:
generated electrons from said plasma source are regulated for direction through variations in a quantity of said carrier gas passing through said system, wherein a flow rate of said carrier gas is between approximately 0.01 to approximately 2 standard liters per minute.

21. The system of claim 1, wherein:
a distance between a part of said plasma source and said source vapor is adjustable.

22. The system of claim 1, further comprising:
said chamber.

23. The system of claim 1, further comprising:
a power source constructed to provide energy to each of said plurality of plasma source units.

24. A method comprising:
depositing a coating on a substrate, said coating deposited via a plurality of plasma source units directed toward a carrier gas, said carrier gas comprising a coating material from at least a first source vapor, said coating material directed toward said substrate via said carrier gas in a chamber under vacuum, said plurality of plasma source units constructed to ionize said source vapor and atoms of atoms of said carrier gas, wherein the substrate is coated with said coating material via directed vapor deposition, said plurality of plasma source units constructed to balance plasma flux for two directions at once such that said plasma flux does not provide a net directionality to said coating material as said coating material reaches said substrate and allows substantially uniform access of said coating material to said substrate.

25. The method of claim 24, further comprising:
rapidly switching polarity of each of said plurality of plasma source units.

26. The method of claim 24, wherein:
said carrier gas comprises oxygen; and
said coating comprises an ion conducting layer.

27. The method of claim 24, wherein:
said carrier gas comprises carbon.

28. The method of claim 24, wherein:
said carrier gas comprises nitrogen.

29. The method of claim 24, wherein:
a pressure of said chamber is between approximately two Pascals and approximately fifty Pascals.

30. The method of claim 24, wherein:
a plasma current of at least one of said plurality of plasma source units is between approximately one amps and approximately one thousand amps.

31. A method comprising:
depositing a coating on a substrate, said coating deposited via a plurality of plasma source units directed toward a carrier gas, said carrier gas comprising a coating material from a source vapor, said coating material directed toward said substrate via said carrier gas in a chamber under vacuum, said plurality of plasma source units constructed to cause said substrate to be coated with said coating material via directed vapor deposition, wherein, said carrier gas is one of substantially pure nitrogen or air, said chamber held at a pressure of approximately eight Pascals, each of said plurality of plasma source units is operated at a plasma current of between approximately 150 amps and 200 amps.
